(19) United States
(12) Patent Application Publication
(10) Pub. No.: US 2014/0113425 A1
(43) Pub. Date: Apr. 24, 2014

(54) METHOD OF FABRICATING SEMICONDUCTOR DEVICE

(71) Applicant: UNITED MICROELECTRONICS CORP., Hsin-Chu City (TW)

(72) Inventors: An-Chi Liu, Tainan City (TW); Chun-Hsien Lin, Tainan City (TW)

(73) Assignee: UNITED MICROELECTRONICS CORP., Hsin-Chu City (TW)

(21) Appl. No.: 13/656,764

(22) Filed: Oct. 22, 2012

(51) Int. Cl. H01L 21/336

(52) U.S. Cl. 438/302; 257/E21.409

(57) ABSTRACT

A method of fabricating a semiconductor device includes the following steps. At first, at least a gate structure is formed on a substrate. Subsequently, a first material layer and a second material layer sequentially formed on the substrate conformally cover the gate structure. Subsequently, an implantation process is performed on the second material layer, and a wet etching process is further performed to remove a part of the second material layer to form a remaining second material layer. Furthermore, a dry etching process is performed to remove a part of the remaining second material layer to form a partial spacer.

### BACKGROUND OF THE INVENTION

1. Field of the Invention

The present invention relates to a method of fabricating a semiconductor device, and more particularly to a method of fabricating a semiconductor device including a non-conformal stress layer between conductive layers in order to reduce the formation of voids in the dielectric layer disposed on the stress layer.

2. Description of the Prior Art

With the trend of miniaturization of the electronic products and peripherals, research about thin structures and high integration of the semiconductor devices have become the essential subjects of developing aspects in the industry. In the fabrication of semiconductor integrated circuits (ICs), semiconductor devices are generally connected by several metallic interconnecting layers commonly referred to as multi-level interconnects.

The multi-level interconnects usually include dielectric layers and metal layers disposed alternately. The process of manufacturing multi-level interconnects includes the following steps. A patterned conductive layer such as gate electrode or source/drain region is formed on a substrate, followed by forming a dielectric layer covering the conductive layer. Subsequently, a plurality of contact plugs electrically connected to the conductive layer is formed in the dielectric layer. Then, another conductive layer such as metal line electrically connected to the contact plugs is formed on the dielectric layer. After the formation of the conductive and dielectric layers, a passivation layer is finally selectively disposed thereon to complete the formation of the multi-level interconnects.

The semiconductor processes can be very different according to different requirements, if the integration of semiconductor devices in the semiconductor integrated circuits increases, or the thickness of the formed conductive layer is too large, the step coverage effect of the following formed dielectric layer or passivation layer covering the conductive layer may be affected. For example, voids may be found when the dielectric layer or the passivation layer is used to fill in the space between two conductive layers, or cracks may be found in the dielectric layer or the passivation layer due to the stress at the corner of the conductive layer caused by the straight interface between the dielectric layer or the passivation layer and the conductive layer.

Consequently, how to prevent defects such as voids from being formed in the dielectric layer or the passivation layer in order to improve the performances of the semiconductor device is still an important issue in the field.

### SUMMARY OF THE INVENTION

An objective of the present invention is therefore to provide a method of fabricating a semiconductor device to avoid the formation of defects such as voids in the dielectric layer disposed on the conductive layer.

According to one exemplary embodiment of the present invention, a method of fabricating a semiconductor device includes the following steps. At first, at least a gate structure is formed on a substrate. Subsequently, a first material layer and a second material layer are sequentially formed on the substrate, and the first material layer and the second material layer conformally cover the gate structure. Then, an implantation process is performed on the second material layer, and a wet etching process is further performed to remove a part of the second material layer to form a remaining second material layer. Furthermore, a dry etching process is performed to remove a part of the remaining second material layer to form a partial spacer.

According to another exemplary embodiment of the present invention, a method of fabricating a semiconductor device includes the following steps. At first, at least a gate structure is formed on a substrate. Subsequently, a first material layer and a second material layer are sequentially formed on the substrate, the first material layer and the second material layer conformally cover the gate structure, and the second material layer includes a stress layer. After that, an implantation process is performed on the second material layer, and a wet etching process is further performed to remove a part of the second material layer to form a remaining second material layer.

The implantation process and the wet etching process are sequentially performed in the present invention to modify the original profile of the second material layer, therefore, a curved profile of the partial spacer or the remaining second material layer can be obtained and used to substitute for a part of a vertical profile of a sidewall of the gate structure, in order to provide a reverse half-Y shaped profile at two sides of the gate structure before forming the dielectric layer such as inter-layer dielectric (ILD) layer. Accordingly, the formation of defects such as voids between the gate structures can be reduced during the dielectric layer process. Furthermore, the insulation and protection functions of the dielectric layer can be improved, and the performances of the semiconductor device may be enhanced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 6 are schematic diagrams illustrating a method for fabricating a semiconductor device according to a preferred exemplary embodiment of the present invention.

FIG. 7 is a schematic diagram illustrating a method for fabricating a semiconductor device according to another preferred exemplary embodiment of the present invention.

FIG. 8 is a schematic diagram illustrating a method for fabricating a semiconductor device according to the other preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

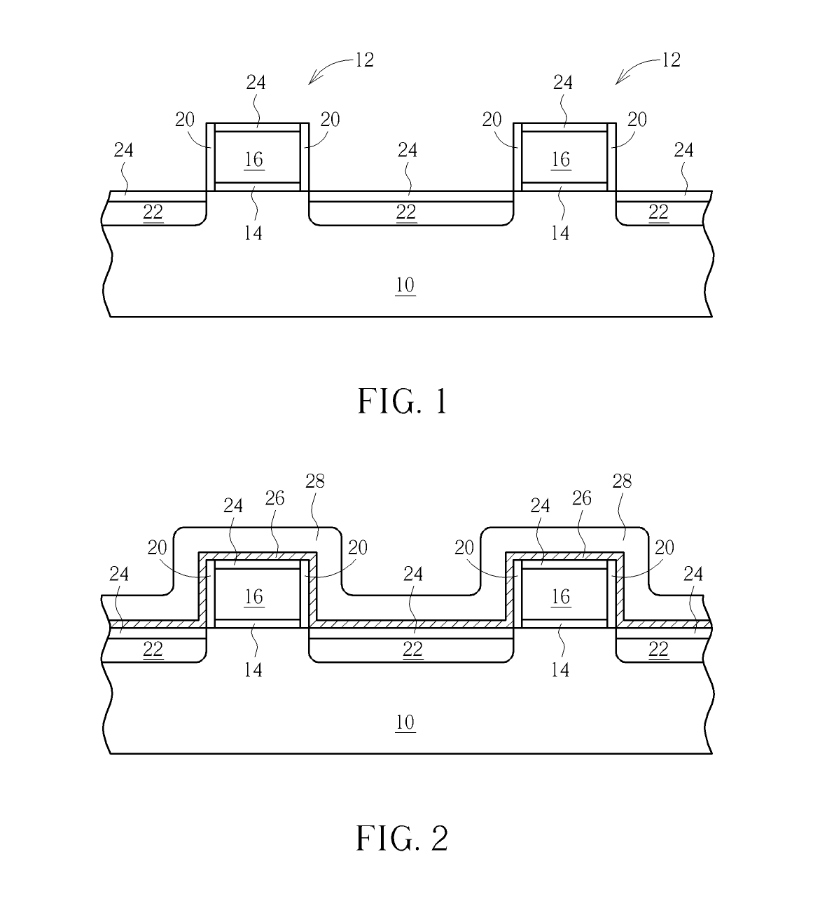

Please refer to FIG. 1 through FIG. 6, which are schematic diagrams illustrating a method for fabricating a semiconductor device according to a preferred exemplary embodiment of the present invention. As shown in FIG. 1, at least a gate structure 12 is formed on a substrate 10. The substrate 10 may be a semiconductor substrate composed of silicon, gallium arsenide (GaAs), silicon on insulator (SOI) layer, epitaxial layer, SiGe layer or other semiconductor materials. The gate structure 12 includes a gate dielectric layer 14, a gate conductive layer 16, a cap layer (not shown) and a spacer 20. The gate dielectric layer 14 could be a low-k (low dielectric constant) gate dielectric layer made of silicon oxide, nitridation silicon oxide or other low-k material, or a high-k (high dielectric constant) gate dielectric layer. The material of the high-k gate dielectric layer may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or combination thereof. Furthermore, the gate conductive layer 16 may be made of undoped polysilicon, polysilicon having N+ dopants, or a metal layer having the specific work function. The cap layer made of silicon oxide, silicon nitride, or silicon oxynitride (SiON) could be selectively disposed on the gate conductive layer 16. The spacer 20 may be a monolayered structure or multilayered structure or may include a liner, or be a composition thereof. The material of the spacer 20 could be high temperature oxide (HTO), silicon nitride, silicon oxide, or HCD-SiN formed by hexachlorodisilane (Si₂Cl₆). Before forming the spacer 20, a light doped source/drain (LDD) region (not shown) could be formed in the substrate 10 at two sides of gate dielectric layer 14. As the processes of forming the gate structure 12 are commonly known to those skilled in the art, the details are omitted herein for brevity.

Subsequently, a source/drain region 22 is formed at two sides of the gate structure 12 in the substrate 10 through an ion implantation process by using the spacer 20 and the cap layer as a mask and implanting dopants having the suitable conductive type such as n-type or p-type according to process requirements. Furthermore, an annealing process could be carried out to activate the source/drain region 22.

After the formation of the source/drain region 22, the cap layer can be removed, and a salicide process is further performed by firstly forming a metal layer (not shown) selected from a group consisting of cobalt, titanium, nickel, platinum, palladium, and molybdenum on the substrate 10, then using at least one rapid thermal anneal process to make the metal layer react with the exposed silicon layer for forming a metal silicide layer 24 such as nickel silicide (NiSi) layer on the gate structure 12 and the source/drain region 22, and the un-reacted metal layer is later removed. Moreover, even though the light doped source/drain region, the spacer 20, and the source/drain region 22 are formed sequentially in the illustrated exemplary embodiment, the order of fabricating the spacers and doping regions could also be adjusted according to the demands of the product. Furthermore, the metal silicide layer 24 on the gate structure 12 and the metal silicide layer 24 on the source/drain region 22 could also be formed in different processes, or the metal silicide layer 24 can be selectively formed on the source/drain region 22 while not being formed on the gate structure 12, or the metal silicide layer 24 can be selectively formed on a portion of the source/drain region 22 after subsequent interlayer dielectric deposition and contact patterning process and these modifications are all within the scope of the present invention.

As shown in FIG. 2, a first material layer 26 and a second material layer 28 are sequentially formed on the substrate 10, and the first material layer 26 and the second material layer 28 conformally cover the gate structure 12. The first material layer 26 may preferably be a non-stress layer such as an oxide film, the second material layer 28 may preferably be a stress layer such as a nitride film, and the first material layer 26 could also serve as a barrier layer between the substrate 10 and the second material layer 28, but not limited thereto. The first material layer 26 and the second material layer 28 can be formed through a chemical vapor deposition (CVD) process including a plasma enhanced chemical vapor deposition (PECVD) process, a low pressure chemical vapor deposition (LPCVD), a sub-atmospheric chemical vapor deposition (SACVD) process, or an atomic layer deposition (ALD) process, etc. In this exemplary embodiment, the first material layer 26 is a non-stress layer made of silicon oxide film which has a thickness substantially around 50 angstroms (Å), and the second material layer 28 is a stress layer made of silicon nitride film which has a thickness substantially around 250 Å, but is not limited thereto. Furthermore, the first material layer 26 totally covers the source/drain region 22 and the gate structure 12.

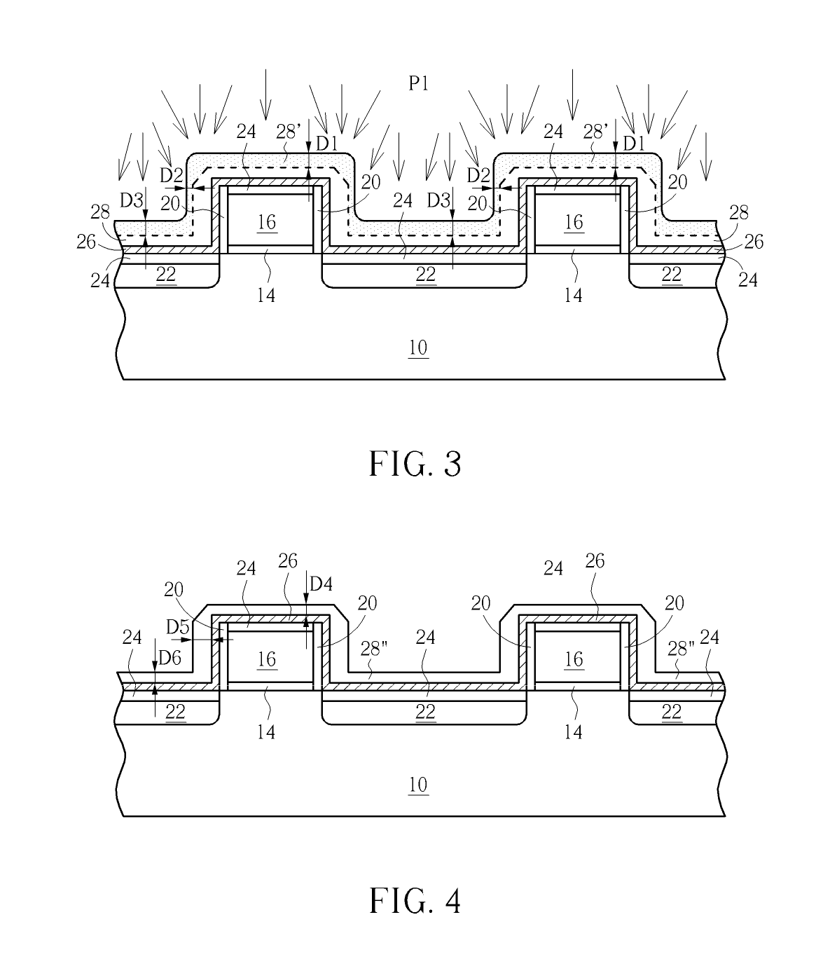

As shown in FIG. 3, an ion implantation process P1 is performed on the second material layer 28, and the conductive type of dopants used in this ion implantation process P1 is the same as a conductive type of dopants of the source/drain region 22. It is appreciated that, the ion implantation process P1 includes various implanting tilt-angles, and the direction toward which the dopants get into the second material layer 28 is referred to by the arrows in FIG. 3. It is noted that, the dopants bombard the exposed horizontal surface more frequently than the exposed vertical surface. Accordingly, an implanted depth D1 of dopants in the second material layer 28 overlapping a top of the gate structure 12 and an implanted depth D3 of dopants in the second material layer 28 overlapping a top of the source/drain region 22 can be larger than an implanted depth D2 of dopants in the second material layer 28 overlapping a sidewall of the gate structure 12. In other words, a profile of the doped second material layer 28′ is formed according to the implanting tilt-angle distribution status. Moreover, the doped second material layer 28′ preferably does not contact the first material layer 26, therefore, the doped second material layer 28′ is overall located on the second material layer 28 without dopants. In this exemplary embodiment, the conductive type of the dopants in the source/drain region 22 and the conductive type of the dopants in the doped second material layer 28′ are the same as p-type, and a ratio of the doped second material layer 28′ such as a ratio of p-doped silicon nitride layer to the original second material layer 28 made of silicon nitride (as shown in FIG. 2) is substantially around 1% to 2%.

As shown in FIG. 4, a wet etching process is performed to remove a part of the second material layer 28 i.e. the doped second material layer 28′ to form a remaining second material layer 28″. An etchant of the wet etching process preferably has a selectivity between a material of the second material layer 28 (undoped material) and a material of the doped second material layer 28′ (doped material). In other words, when the etchant is used in the wet etching process, an etching rate of the second material layer 28 is preferably different from an etching rate of the doped second material layer 28′. Accordingly, a thickness D4 of the remaining second material layer 28″ overlapping the top of the gate structure 12 and a thickness D6 of the remaining second material layer 28″ overlapping the top of the source/drain region 22 can be smaller than a thickness D5 of the remaining second material layer 28″ overlapping the sidewall of the gate structure 12. In this exemplary embodiment, the hot phosphoric acid having a temperature between 120 degrees centigrade (° C.) and 150° C. may serve as the etchant of the wet etching process, and the etching rate of the doped region 28′ (500 Å per minute, 500 Å/min) is larger than the etching rate of the original second material layer 28 (350 Å per minute, 350 Å/min). Accordingly, after totally removing the doped second material layer 28′, the second material layer 28 may still partially remain on the first material layer 26 to serve as the remaining second material layer 28″. Furthermore, a thickness of the remaining second material layer 28″ is inversely corresponding to the implanted depth of dopants in the second material layer 28, i.e. the profile of the doped second material layer 28′.

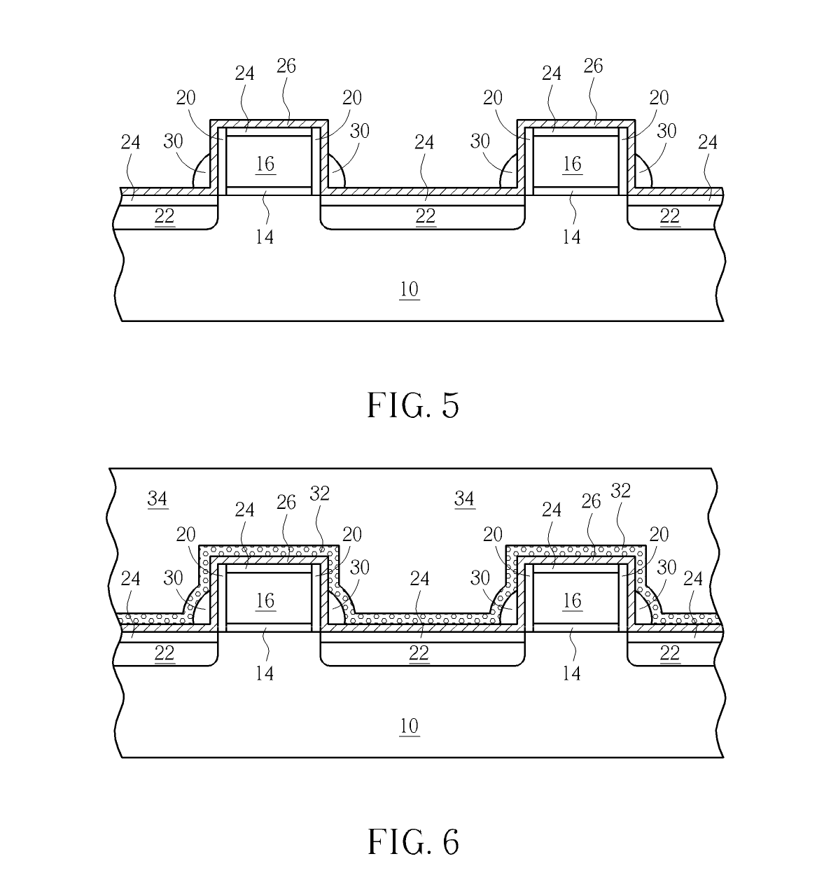

As shown in FIG. 5, a dry etching process is further performed to remove a part of the remaining second material layer 28″ to form a partial spacer 30. The dry etching process includes an anisotropic etching process. Furthermore, the first material layer 26 can serve as an etching stop layer, therefore, during the dry etching process, the first material layer 26 which still totally covers the source/drain region 22 and the gate structure 12 may prevent the formed metal silicide layer 24 in the source/drain region 22 and the gate structure 12 from being damaged by etching processes or other processes.

After the dry etching process, as shown in FIG. 6, a contact etch stop layer (CESL) 32 and an inter-layer dielectric (ILD) layer 34 are deposited sequentially on the substrate 10. The CESL 32 may provide stress to the channel region (not shown) under the gate structure 12 and between the source/drain region 22 in order to improve the carrier mobility in the channel region and enhance the semiconductor device performances. Due to the stress material of the second material layer 28, the partial spacer 30 may provide stress to the channel region as well. In this exemplary embodiment, a material of the CESL 32 is preferably the same as the material of the partial spacer 30, and a stress type of CESL 32 is preferably the same as a stress type of the partial spacer 30, for example, the CESL 32 and the second material layer 28 may be both made of silicon nitride and provide compressive stress. Additionally, the CESL 32 could directly contact the partial spacer 30, i.e. the process for forming other films between CESL 32 and the partial spacer 30 to improve adhesion effect can be omitted.

It is appreciated that the curved profile of the partial spacer 30 may substitute for a part of the vertical profile of the sidewall of the gate structure 12, therefore, instead of a common vertical profile, a reverse half-Y shaped profile is provided at two sides of the gate structure 12 before the formation of ILD layer 34. The material of the ILD layer 34 can therefore smoothly fill up the space between the gate structures 12.

In other exemplary embodiments, the dry etching process illustrated for forming a partial spacer may be omitted, and the remaining second material layer 28″ may directly serve as CESL. More specifically, the remaining second material layer 28″ formed by partially removing the second material layer 28 made of stress material should be able to produce stress as well, and the stress is predetermined to be provided by the CESL 32 toward the channel region in the previously illustrated embodiment.

The present invention is not limited to the previous illustrated exemplary embodiment; the present invention may be applicable to be integrated into various metal gate processes. To simplify the explanation and clarify the comparison, in the following exemplary embodiment, the same components are denoted by the same numerals, and the differences are discussed while the similarities are not described again.

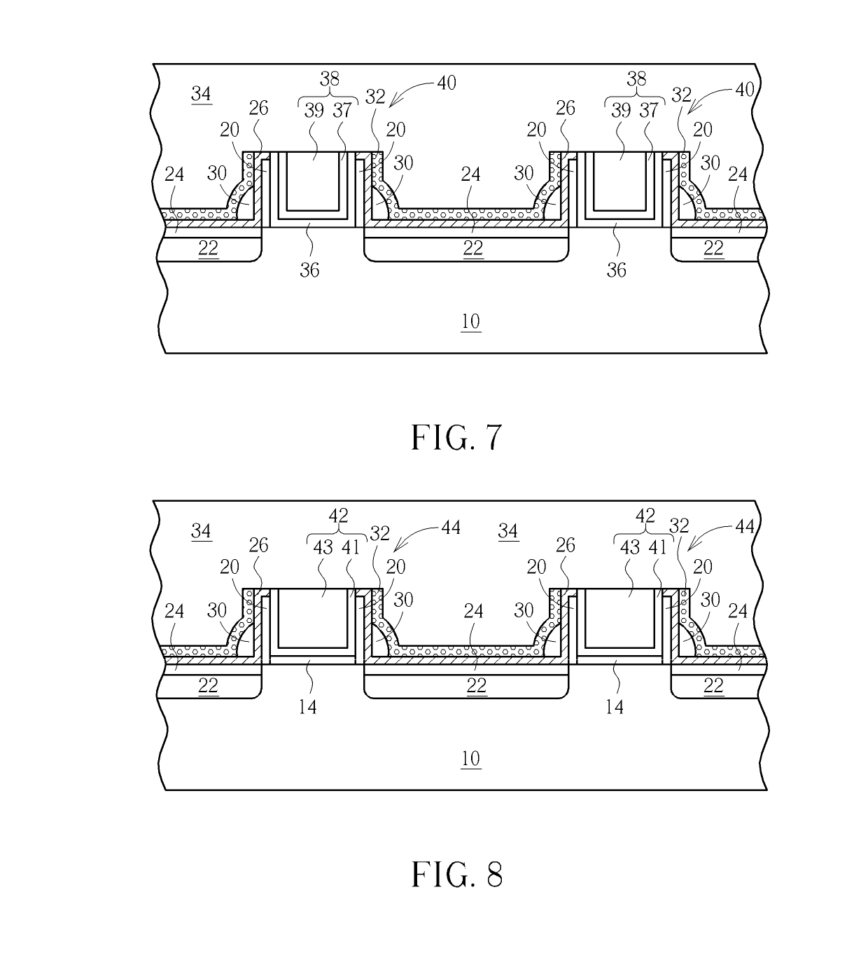

Please refer to FIG. 7, which is a schematic diagram illustrating a method for fabricating a semiconductor device according to another preferred exemplary embodiment of the present invention. As shown in FIG. 7, the present invention may be integrated into metal gate processes such as a high-k last process integrated into a gate-last process. The provided structure is similar to that of the gate structure 12 having the partial spacer 30 as shown in FIG. 5, but a cap layer is formed instead of the metal silicide layer 24 on the gate conductive layer 16 according to the different process requirements for forming metal gate. Furthermore, the CESL 32 is formed, and the CESL 32 covers the provided structure. Subsequently, an opening (a gate trench) is formed between the spacer 20 by removing a part of the CESL 32 such as the CESL 32 overlapping the gate conductive layer 16 and the gate dielectric layer 14, a part of the first material layer 26, the cap layer on the gate conductive layer 16, the gate conductive layer 16 and the gate dielectric layer 14, then, a high-k gate dielectric layer 36 and a corresponding metal gate conductive layer 38 are further formed to fill the opening for forming a metal gate structure 40. Moreover, the ILD layer 34 may be further deposited on the metal gate structure 40.

It should be noted that, before forming the opening, a sacrificial dielectric layer (not shown) may be formed covering the gate structure and filling up the space between the gate structures, and then a planarization process is performed to remove the sacrificial dielectric layer until exposing the cap layer. Besides, the sacrificial dielectric layer may remain between the gate structures 40 to serve as a portion of the ILD layer 34 or the sacrificial dielectric layer may be fully removed and then the ILD layer 34 may be further deposited on the metal gate structure 40.

Please refer to FIG. 8, which is a schematic diagram illustrating a method for fabricating a semiconductor device according to the other preferred exemplary embodiment of the present invention. As shown in FIG. 8, the present invention may be integrated into metal gate processes such as a high-k first process integrated into a gate-last process. The provided structure is similar to that of the gate structure 12 having the partial spacer 30 as shown in FIG. 5, but a cap layer is formed instead of the metal silicide layer 24 on the gate conductive layer 16 according to the different process requirements for forming metal gate. Furthermore, the CESL 32 is formed, and the CESL 32 covers the provided structure. Subsequently, an opening (a gate trench) could be formed between the spacer 20 by removing a part of the CESL 32, a part of the first material layer 26, the cap layer on the gate conductive layer 16 and the gate conductive layer 16. Afterward, a corresponding metal gate conductive layer 42 is formed to fill the opening on the gate dielectric layer 14 made of high-k gate dielectric material for forming a metal gate structure 44. Similarly, the ILD layer 34 may be further deposited on the metal gate structure 44.

As shown in FIG. 7 and FIG. 8, the metal gate conductive layer 38/42 may include a work function tuning layer 37/41 and a conductive layer 39/43. The work function tuning layer 37/41 is disposed on the high-k gate dielectric layer 36/14 and the side walls of the opening for tuning the work function of the metal gate structure 40/44 appropriate for an n-type metal oxide semiconductor (nMOS) transistor or p-type metal oxide semiconductor (pMOS) transistor. For a use in an nMOS transistor, the work function tuning layer 37/41 having a work function ranging between 3.9 eV and 4.5 eV may include titanium aluminide (TiAl), zirconium aluminide (ZrAl), tungsten aluminide (WAl), tantalum aluminide (TaAl), or hafnium aluminide (HfAl), but is not limited thereto. For a use in a pMOS transistor, the work function tuning layer 37/41 having a work function ranging between 4.8 eV and 5.2 eV may include titanium nitride (TiN), tantalum nitride (TaN), tantalum carbide (TaC), but is not limited thereto. The conductive layer 39/43 may be made of conductive material including metal such as aluminum (Al), molybdenum (Mo), chromium (Cr), tungsten (W), copper (Cu) or any combination thereof.

In conclusion, the implantation process and the wet etching process are sequentially performed in the present invention to modify the original profile of the second material layer, therefore, a curved profile of the partial spacer or the remaining second material layer can be obtained and used to substitute for a part of a vertical profile of a sidewall of the gate structure, in order to provide a reverse of half-Y shaped profile at two sides of the gate structure before forming the dielectric layer such as inter-layer dielectric (ILD) layer. Accordingly, the formation of defects such as voids between the gate structures can be reduced during the dielectric layer process. Consequently, the insulation and protection functions of the dielectric layer can be improved, and the performances of the semiconductor device may be enhanced.

Those skilled in the art will readily observe that numerous modifications and alterations of the device and method may be made while retaining the teachings of the invention. Accordingly, the above disclosure should be construed as limited only by the metes and bounds of the appended claims.

1: A method of fabricating a semiconductor device, comprising:
forming at least a gate structure on a substrate;
sequentially forming a first material layer and a second material layer on the substrate, wherein the first material layer and the second material layer conformally cover the gate structure;
performing an implantation process on the overall second material layer;
performing a wet etching process to remove a part of the second material layer to form a remaining second material layer; and
performing a dry etching process to remove a part of the remaining second material layer to form a partial spacer.

2: The method of fabricating a semiconductor device according to claim 1, further comprising forming a source/drain region at two sides of the gate structure.

3: The method of fabricating a semiconductor device according to claim 2, wherein a conductive type of dopants in the source/drain region is the same as a conductive type of dopants used in the implantation process.

4: The method of fabricating a semiconductor device according to claim 2, wherein the first material layer covers the source/drain region during the wet etching process and the dry etching process.

5: The method of fabricating a semiconductor device according to claim 1, wherein the implantation process comprises various implanting tilt-angles.

6: The method of fabricating a semiconductor device according to claim 1, wherein before the wet etching process, an implanted depth of dopants in the second material layer overlapping a top of the gate structure is larger than an implanted depth of dopants in the second material layer overlapping a sidewall of the gate structure.

7: The method of fabricating a semiconductor device according to claim 6, wherein after the wet etching process, a thickness of the remaining second material layer overlapping a top of the gate structure is smaller than a thickness of the remaining second material layer overlapping a sidewall of the gate structure.

8: The method of fabricating a semiconductor device according to claim 1, wherein the remaining second material layer covers a top of the gate structure.

9: The method of fabricating a semiconductor device according to claim 1, wherein the second material layer comprises a stress layer.

10: The method of fabricating a semiconductor device according to claim 9, further comprising forming a contact etching stop layer (CESL) after the dry etching process, wherein a stress type of CESL is the same as a stress type of the partial spacer.

11: The method of fabricating a semiconductor device according to claim 10, wherein the contact etching stop layer directly contacts the partial spacer.

12: The method of fabricating a semiconductor device according to claim 1, wherein the first material layer comprises silicon oxide, and the second material layer comprises silicon nitride.

13: A method of fabricating a semiconductor device, comprising:
forming at least a gate structure on a substrate;
sequentially forming a first material layer and a second material layer on the substrate, wherein the first material layer and the second material layer conformally cover the gate structure, and the second material layer comprises a stress layer;
performing an implantation process on the overall second material layer; and
performing a wet etching process to remove a part of the second material layer to form a remaining second material layer.

14: The method of fabricating a semiconductor device according to claim 13, further comprising forming a source/drain region at two sides of the gate structure.

15: The method of fabricating a semiconductor device according to claim 14, wherein a conductive type of dopants in the source/drain region is the same as a conductive type of dopants used in the implantation process.

16: The method of fabricating a semiconductor device according to claim 14, wherein the first material layer covers the source/drain region during the wet etching process.

17: The method of fabricating a semiconductor device according to claim 13, wherein the implantation process comprises various implanting tilt-angles.

18: The method of fabricating a semiconductor device according to claim 13, wherein before the wet etching process, an implanted depth of dopants in the second material layer overlapping a top of the gate structure is larger than an implanted depth of dopants in the second material layer overlapping a sidewall of the gate structure.

19: The method of fabricating a semiconductor device according to claim 13, wherein after the wet etching process, a thickness of the remaining second material layer overlapping a top of the gate structure is smaller than a thickness of the remaining second material layer overlapping a sidewall of the gate structure.

20: The method of fabricating a semiconductor device according to claim 13, further comprising forming a contact etching stop layer (CESL) after the wet etching process, wherein a stress type of CESL is the same as a stress type of the second material layer.
